(19) United States
(12) Patent Application Publication
(10) Pub. No.: US 2025/0107448 A1
(43) Pub. Date: Mar. 27, 2025

(54) PIEZO-ELECTRIC ACTUATOR DEVICE WITH A FORCE LIMITING STRUCTURE

(71) Applicant: Boréas Technologies Inc., Bromont (CA)

(72) Inventor: Guillaume CHAUVETTE, Bromont (CA)

(21) Appl. No.: 18/723,669

(22) PCT Filed: Dec. 20, 2022
(86) PCT No.: PCT/CA2022/051865

§ 371 Date: Jun. 24, 2024

Related U.S. Application Data
(60) Provisional application No. 63/293,227, filed on Dec. 23, 2021.

(51) Int. Cl. H10N 30/30; H03K 17/96; H10N 30/88

(52) U.S. Cl. CPC H10N 30/302; H03K 17/9643; H10N 30/88; H03K 2217/96062

(57) ABSTRACT

A “mechanism” in series with the piezoelectric actuator that limits the amount of force that can be applied to the piezoelectric actuator, but that does not interfere when force levels are acceptable (normal use). Accordingly, the piezo-electric actuator system includes a first resilient member configured for generating a preload force; and a first thrust member configured for applying the preload force to a first abutment surface when the input force is not applied to the first piezo-electric actuator and to the first piezo-electric actuator when the input force is applied to the first piezo-electric actuator.

### TECHNICAL FIELD

The present disclosure relates to a piezo-electric actuator device, and in particular to a piezo-electric actuator device with a force limiting structure.

### BACKGROUND

Piezo-electric actuators may be used to replace buttons in electronic devices. Applying a force to a piezo-electric actuator will generate a tension which can be detected by control electronics. A voltage signal can then be sent to the piezo-electric actuator to produce haptic feedback to let the user know the action has been performed.

There are multiple advantages to use piezo-electric actuators as a replacement for traditional switches, e.g. piezo-electric actuators have the ability to detect different force thresholds instead of simple on/off states, and they can produce a variety of haptic feedbacks, e.g. clicks, buzz, complex waveforms, etc., to enrich the user experience.

Piezo-electric actuators may have some limitations, e.g. the amount of displacement they can produce or be submitted to is often small when compared to their variation of height. Piezo-electric actuators can resist moderate force levels, but they are often submitted to high forces and impacts during drop tests.

Using a system to limit the deformation of a piezo-electric actuator is not always possible since the variation of the height tolerance of the piezo-electric actuator can be more than the maximum allowable deformation.

An object of the present disclosure is to provide a force limiter mechanism to ensure that the force applied to a piezo-electric actuator is less than a maximum allowable.

### SUMMARY

Accordingly, a first apparatus includes a piezo-electric actuator device for mounting on a frame of an electronic device, comprising:
a first pushbutton mounted on the frame of the electronic device with a first gap between the first pushbutton and a hard stop on the frame;
a first piezo-electric actuator configured for receiving an input force from the first pushbutton and generating a first input voltage signal when the input force exceeds an actuation force;
a first resilient member configured for generating a preload force; and
a first thrust member in contact with the first resilient member configured for applying the preload force to a first abutment surface when the input force is not applied to the first piezo-electric actuator, configured for applying at least a portion of the preload force to the first piezo-electric actuator when the input force is applied to the first piezo-electric actuator, and configured for moving away from the first abutment surface when the input force is greater than the preload force to enable the first pushbutton to engage the hard stop, thereby limiting the input force on the first piezo-electric actuator.

In any of the above-identified embodiments the first piezo-electric actuator may also be configured for receiving a first output voltage signal and generating a first haptic response to the first pushbutton in response to the input force exceeding the actuation force.

In any of the above-identified embodiments the device may further comprise a second gap, larger than the first gap, between the first thrust member and a second abutment surface, whereby the first pushbutton engages the first hard stop on the frame before the first resilient member is fully compressed or the first thrust member engages the second abutment surface.

In any of the above-identified embodiments the device may comprise a resilient seal between the first pushbutton and the frame configured to define the first gap.

In any of the above-identified embodiments the first piezo-electric actuator may be mounted within a first recess in the frame; wherein the pushbutton may be mounted within a second recess in the frame; wherein the resilient member and the thrust member may be mounted within a third recess in the frame.

In any of the above-identified embodiments the first recess, the second recess and the third recess may continuously extend through the frame; wherein the first recess may be in between the second recess and the third recess; wherein a first shoulder between the first recess and the second recess may include the hard stop, and a second shoulder between the first recess and the third recess may include the first abutment surface.

In any of the above-identified embodiments the first abutment surface may be provided in a top of the third recess.

In any of the above-identified embodiments the first pushbutton may include a pedestal extending into contact with the first piezo-electric actuator.

In any of the above-identified embodiments the first resilient member may comprise a leaf spring, and the first thrust member may comprises a plate.

In any of the above-identified embodiments the frame may comprise:
a base having the third recess extending into an upper side thereof; and
a top cover mounted on the base having the first recess extending into a first side thereof, and the second recess extending into a second side thereof.

In any of the above-identified embodiments the pushbutton may comprise a virtual button contiguous with an outer portion of the frame.

In any of the above-identified embodiments the frame may include a cavity for receiving at least one of the first resilient member, the first thrust member, the first piezo-electric actuator and the first pushbutton;
wherein the cavity may include projections extending into either side thereof; and
wherein the projections may form the first hard stop on one side, and the first abutment surface on another side.

In any of the above-identified embodiments the device may further comprise:
a second piezo-electric actuator configured for receiving the input force from the first pushbutton and generating a second input voltage signal, and configured for receiving a second output voltage signal and generating a second haptic response to the pushbutton;
a second resilient member configured for generating a second preload force; and
a second thrust member configured for applying the second preload force to a third abutment surface when the input force is not applied to the second piezo-electric actuator and for applying at least a portion of the preload force to the second piezo-electric actuator when the input force is applied to the second piezo-electric actuator, and configured for moving away from the third abutment surface when the input force is greater than the preload force to enable the first pushbutton to engage the hard stop, thereby limiting the input force on the second piezo-electric actuator;
wherein a third gap, larger than the first gap, between the second thrust member and a fourth abutment surface, whereby the first pushbutton engages the frame before the second resilient member is fully compressed or the second thrust member engages the third abutment surface.

In any of the above-identified embodiments the resilient member and the thrust member may be mounted in the pushbutton.

In any of the above-identified embodiments the first abutment surface and a second abutment surface may be provided in a groove in the pushbutton.

In any of the above-identified embodiments the pushbutton may include a housing element for supporting the resilient member and the thrust member on the piezo-electric actuator and the pushbutton.

In any of the above-identified embodiments wherein the housing includes projections extending into a cavity in the frame; wherein one side of the projections are configured for engaging a bottom of the cavity to act as the hard stop for the housing, and another side of the projections forms the first abutment surface.

### BRIEF DESCRIPTION OF THE DRAWINGS

Some example embodiments will be described in greater detail with reference to the accompanying drawings, wherein:

FIG. 1 is an exploded view in accordance with an example of a piezo-electric actuator device;

FIG. 2 is a cross-sectional view of the piezo-electric actuator device of FIG. 1;

FIG. 3 is an exploded view of the piezo-electric actuator device of FIG. 1 mounted in an electronic device;

FIG. 4A is a cross-sectional view in accordance with another example of a piezo-electric actuator device mounted in an electronic device;

FIG. 4B is a side view of the piezo-electric actuator device of FIG. 4A;

FIG. 5 is a cross-sectional view of the piezo-electric actuator device of FIG. 4A;

FIG. 6 is a cross-sectional view in accordance with another example of a piezo-electric actuator device;

FIG. 7 is an exploded view of the piezo-electric actuator device of FIG. 6 mounted in an electronic device;

FIG. 8A is a side view of the piezo-electric actuator device of FIG. 7;

FIG. 8B is a cross-sectional view of the piezo-electric actuator device of FIG. 7;

FIG. 9 is a cross-sectional view in accordance with another example of a piezo-electric actuator device mounted in an electronic device; and

FIG. 10 is an exploded view of the piezo-electric actuator device of FIG. 9 mounted in an electronic device.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art.

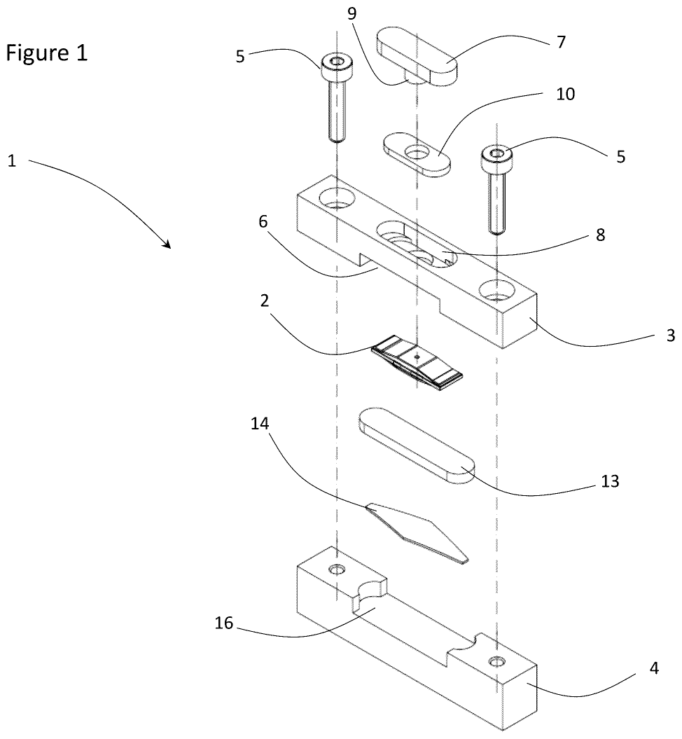

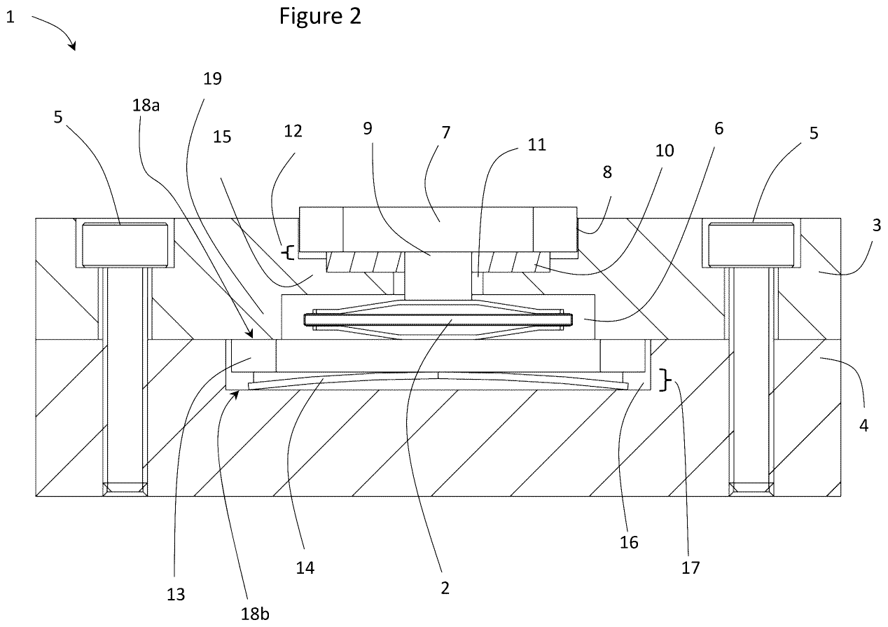

In a first example illustrated in FIGS. 1 and 2, a piezo-electric actuator device 1, includes a piezo-electric actuator (piezo) 2 positioned in a smart device frame, which in the exemplary embodiment comprises a top cover 3 and a bottom base 4 held together with a suitable fastener, e.g. threaded fasteners 5 or an adhesive. In the illustrated example the piezo 2 is positioned within a first recess 6 in the interior surface of the top cover 3, but other arrangements are possible, e.g. exterior surface of the bottom base 4. A pushbutton 7 is received in a second recess 8 in the exterior surface of the top cover 3, and extends outwardly therefrom, although the pushbutton 7 may also be flush therewith or recessed therein. The pushbutton 7 may include a pedestal 9 that extends through a hole 11 in the top cover 3 which may have a smaller diameter than the first recess 6 and/or the second recess 8, into contact with the piezo 2. A gasket seal 10, e.g. comprised of a resilient material, such as foam, may be provided between the pushbutton 7 and the top cover 3, for sealing the hole 11, e.g. within the second recess 8. The gasket seal 10 is configured with a thickness to provide a first gap 12 between the pushbutton 7 and a first shoulder 15 formed at the bottom of the second recess 8. Accordingly, the bottom of the second recess 8 provides a hard stop for the pushbutton 7.

A thrust member 13, e.g. plate, and a resilient member 14, e.g. leaf spring, may be mounted in a third recess 16 extending into an upper side of the bottom base 4, and sandwiched between the top cover 3 and the bottom base 4 with one side of the thrust member 13 in contact with the piezo 2. The nominal height of the resilient member 14 may be larger than the height of the space between the thrust member 13 and the bottom base 4, whereby once assembled, the resilient member 14 is partially compressed and exerts a preload force on the thrust member 13, e.g. perpendicular to the piezo 2 and in an opposite direction to a force exerted on the pushbutton 7, thereby biasing the thrust member 13 into contact with a second shoulder 19 at the top of the third recess 16 forming a first abutment surface 18a. The third recess 16 may be aligned with and open into the first recess 6, but with a diameter wider than the first recess 6, whereby the second shoulder 19 and the first abutment surface 18a is formed by the inner surface of the top cover 3. The resilient member 14 is configured to extend with a thickness to provide a second gap 17 between the thrust member 13 and the bottom of the third recess 16, i.e. a second abutment surface 18b. The preload force is not on the piezo 2, but on the thrust member 13, if no force is applied to the pushbutton 7, there is no force on the piezo 2, but the preload force is still present and is exerted on the second shoulder 19 forming the first abutment surface 18a at the top of the third recess 16. Ideally, the first shoulder 15 and the second shoulder 19 are provided on a projection that extends into a cavity extending into or through the frame, thereby defining the first recess 6, the second recess 8 and the third recess 16.

During normal use, when a force is exerted on the pushbutton 7, a portion of the magnitude of the force is used to squeeze the gasket seal 10, while the remaining portion of the magnitude of the force is applied on the piezo 2. If that remaining portion of magnitude of the force is less than the preload force of the resilient member 14, the thrust member 13 remains in contact with the first abutment surface 18a of the top cover 3, the resilient member 14 does not compress, i.e. deform, any further, and accordingly the bottom base 4, resilient member 14 and the thrust member 13 “act” as a single rigid body. The resilient member 14 is configured, e.g. with a high spring constant, so that the preload force of the resilient member 14 is higher than an actuation force applied on the piezo 2 in normal use to generate an input voltage signal, so that the haptic response generated by the piezo 2 is transmitted to the pushbutton 7 and by consequence to the user instead of moving the thrust member 13 away from the first abutment surface 18a and toward the second abutment surface 18b, e.g. by compressing the resilient member 14. For all embodiments disclosed herein, an electronic circuit 55 may be provided in the device configured for receiving the input voltage signal from the piezo-electric actuators 2 when the input force is exceeding the actuation force of the piezo-electric actuator 2, and in some embodiments generating an output voltage signal for transmission to the piezo-electric actuators 2, which thereby generates the haptic response via the piezo-electric actuator 2 for the user to feel and/or hear.

However, when the “remaining” portion of the magnitude of the force is larger than the preload force of the resilient member 14, the thrust member 13 may lose contact with the top cover 3, i.e. move away from the first abutment surface 18a, and the resilient member 14 may be compressed, e.g. deformed, further. The spring rate of the resilient member 14 may be configured, e.g. low enough, so that when the “remaining” force exceeds the preload force, the force applied on the piezo 2 does not increase as “fast” as if there were no “force limiter mechanism.” The resilient member 14 may “collapse” with little increase on the force it exerts on the piezo 2. The fact that the piezo 2 is in series with the resilient member 14 may have a considerable effect on the equivalent stiffness of the system once “excessive” force is applied.

The stroke, i.e. the first gap 12, that the pushbutton 7 may travel before hitting the hard stop provided on the top cover 3, e.g. bottom of second recess 8, may be less than the stroke, e.g. the second gap 17, that the thrust member 13 may travel before the resilient member 14 is bottomed out, e.g. fully compressed. The stroke, i.e. the first gap 12, between the hard stop and the pushbutton 7 may also be dependent on the tolerances of the assembly components, e.g. the pushbutton 7, the first recess 6, the second recess 8, and the piezo 2, and the deformation that the piezo 2 can withstand.

All of the examples are for switch replacement, however, the piezo-electric actuator devices 1 would also work in other applications, e.g. inertial vibrators, where the thrust member 13 would limit the force on the piezo 2 in the case where the moving mass would create an excessive force on the piezo 2 or in a stylus application where the thrust member 13 limits the force that can be applied on the piezo 2, even if there is excessive force on the stylus tip, in that case, the piezo 2 acts more like a switch/sensor.

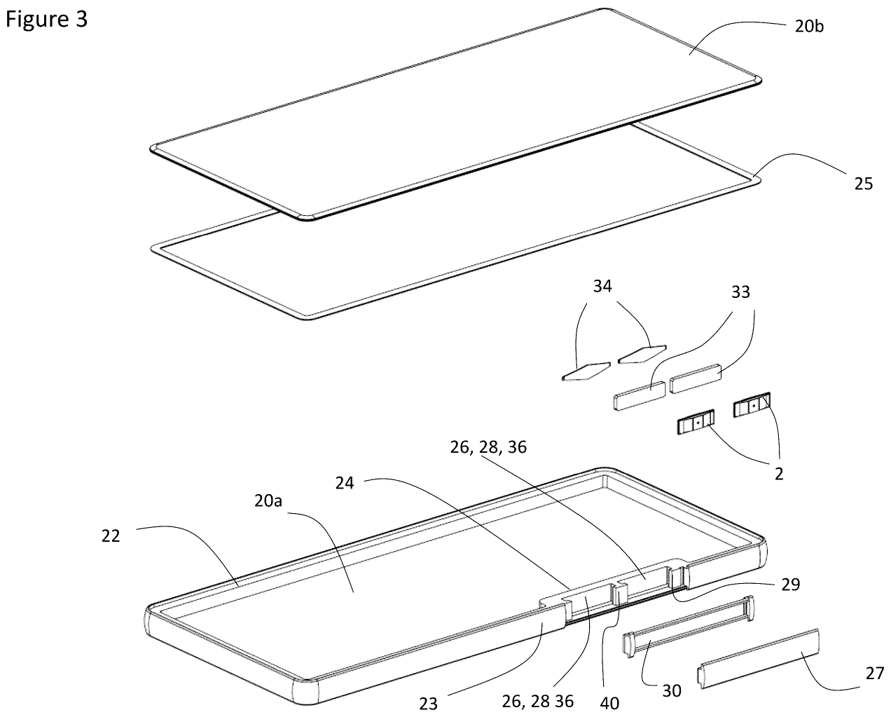

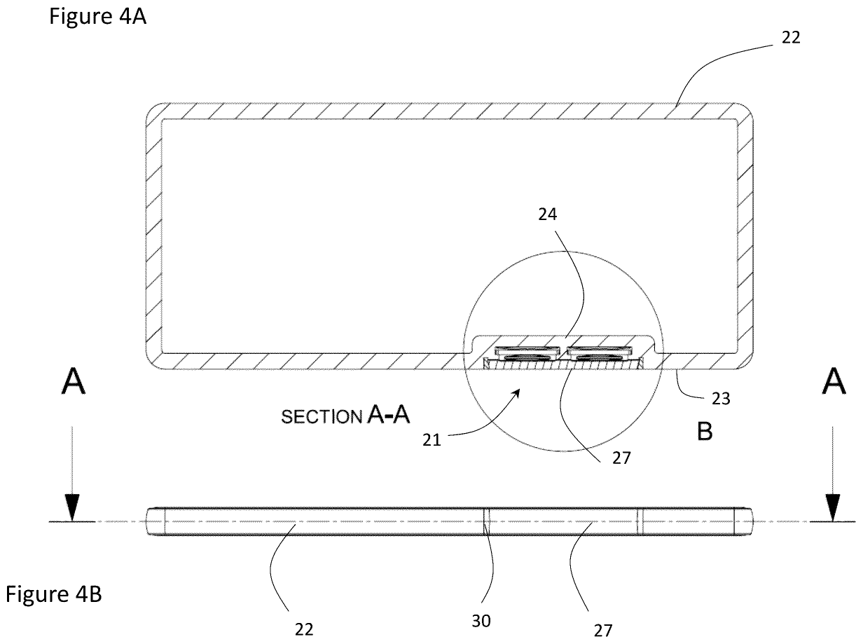

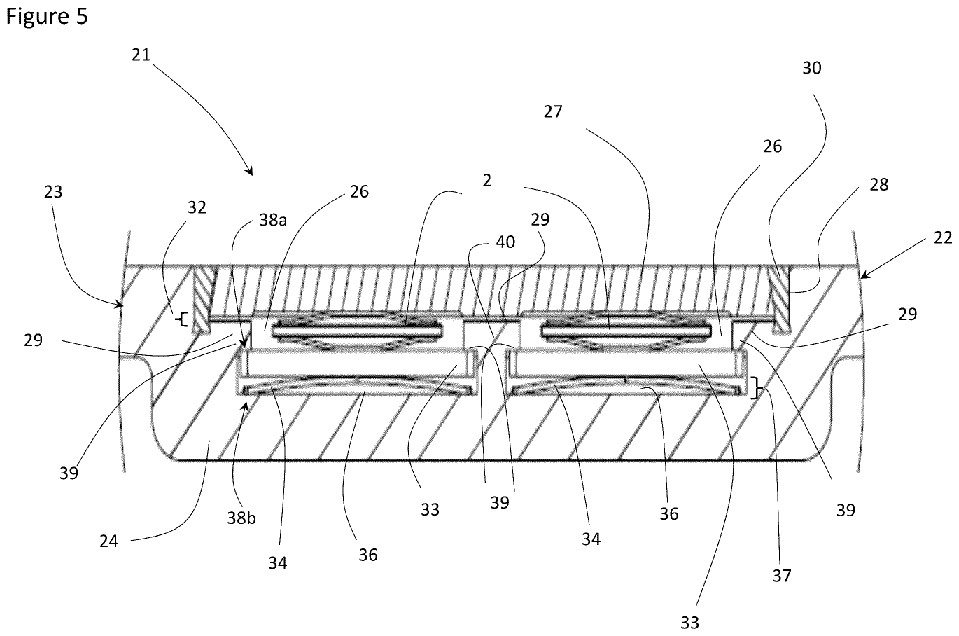

A second example illustrated in FIGS. 3-5, is a piezo-electric actuator device 21, which may be a seamless integration into a frame 22 of an electronic device, e.g. a smart device, in which a top cover 23 and a bottom base 24 may both be integral with the frame 22. A virtual button 27 is in contact with at least one, but preferably two, piezo-electric actuator 2. The piezo-electric actuator device 21 may be used, for example, as a rocker button for volume control. The smart device may include a display screen 20a and a back cover screen 20b mounted on the frame 22 via an adhesive and/or seal 25.

The piezo-electric actuator device 21, includes at least one, preferably two or more, piezo-electric actuators (piezo) 2 positioned between the virtual button 27 and a bottom base 24, ideally formed in the electronic device frame 22. In the illustrated example, each piezo 2 is positioned within a respective first recess 26 or within a single first recess 26 in the exterior surface of the electronic device frame 22, but other arrangements are possible. The virtual button 27 may be received in a second recess 28, and forms a continuous surface with the exterior surface of the electronic device frame 22, although the virtual button 27 may also extend outwardly therefrom or recessed therein. The second recess 28 extends from the outer surface of the electronic device frame 22 beyond, e.g. wider than, the openings of the one or more first recesses 26 forming a first shoulder 29 at the bottom of the second recess 28 and around the one or more first recesses 26. A gasket seal 30, e.g. comprised of a resilient material, such as foam tape, may be provided around the virtual button 27 and between the virtual button 27 and the electronic device frame 22, for sealing the first recess 26 from contamination from the exterior. The gasket seal 30 substantially holds the virtual button 27 in place, but also enables slight movements of the virtual button 27 to transmit the user input to the piezos 2, and to transmit the haptic feedback from the piezos 2 to the user. The gasket seal 30 is configured with a thickness to provide a first gap 32 between the virtual button 27 and the first shoulder 29, i.e. the bottom of the second recess 28. Accordingly, the first shoulder 29, i.e. the bottom of the second recess 28, provides a hard stop for the virtual button 27. Defined another way, the electronic device frame 22 includes a large recess in a side thereof, which has a first widest outer section (second recess 28) for receiving the virtual button 27 and the gasket seal 30, two narrowest middle sections (first recess 26) for receiving the piezos 2, and two slightly wider bottom sections (third recess 36) for receiving thrust members 33 and resilient members 34. The difference between the outer section and the middle sections, i.e. the first shoulder 29, form a hard stop surface for the virtual button 27, and the difference between the middle sections and the bottom sections form a first abutment surface 38a for the thrust members 33. A T-shaped pedestal 40 may be formed in between the bottom sections and the middle sections to provide additional first shoulders 29, hard stop surfaces, and the first abutment surfaces 38a.

Respective thrust members 33 and resilient members 34, e.g. leaf spring, one for each piezo 2, may be mounted in third recesses 36 in the bottom base 24. The third recesses 36 extend from a corresponding one of the first recesses 26 with a slightly larger length and/or width forming the second shoulder 39 between the first recesses 26 and the third recesses 36. The edges of one side of each thrust members 33 are biased by the resilient member 34 and abut against the shoulders 39, i.e. a first abutment surface 38a, resting in contact with the corresponding piezo 2 with the opposite side of the thrust member 33 resting in contact with the resilient member 34. The nominal height of the resilient member 34 may be larger than the height of the space between the thrust member 33 and the bottom base 24, whereby once assembled, the resilient member 34 is partially compressed and exerts a preload force on the thrust member 33. The resilient member 34 is configured with a thickness to provide a second gap 37 between the thrust member 33 and the bottom of the third recess 36, i.e. a second abutment surface 38b.

As above, a portion of the magnitude of the force applied on the virtual button 27 is “used” to squeeze the gasket seal 30, while the “remaining” portion of the magnitude of the applied force is transmitted to the piezo 2. When the force applied on the piezo 2 is smaller than the preload force of the resilient member 34, the thrust member 33 will remain in contact with the bottom base 24 of the frame, i.e. the first abutment surface 38a of the second shoulder 39, but when the force on the piezo 2 is larger than the preload force, then the contact between the thrust member 33 and the frame, e.g. the shoulder 39, may be lost and the resilient member 34 may further compress.

The stroke, e.g. the first gap 32, of the virtual button 27 should to be less than the stroke, e.g. the second gap 37, of the thrust member 33 so that the resilient member 34 does not bottom out, i.e. fully compress, to the second abutment surface 38b. The preload force of the resilient member 34, i.e. the spring constant, is high enough, so the thrust members 33 stay in place during intended use, i.e. normal use and force application: user input detection electrical signal generation+haptic feedback. The spring rate (Stiffness) of the resilient member 34 may be low enough so that the force on the piezos 2 does not exceed the maximum allowable force when the virtual button 27 contacts the frame hard stop, e.g. the first shoulder 29, even if the tolerances are at the worst-case scenario, e.g. maximum material condition/maximum height for the piezo 2. When the virtual button 27 makes contact with the frame hard stop, e.g. the first shoulder 29, any excessive force on the virtual button is transferred directly to the frame, e.g. the bottom base 24.

The second example piezo-electric actuator device 21 could use a “single” seamless virtual button 27 with a single piezo 2, and the first example piezo-electric actuator device 1 could use a “double rocker” button with two piezos 2, i.e. seamless is not exclusive or reserved to 2 buttons use. A volume button may comprise a double rocker button containing two thrust members 33 (plungers), two corresponding piezos 2, and one or a plurality of resilient members 34.

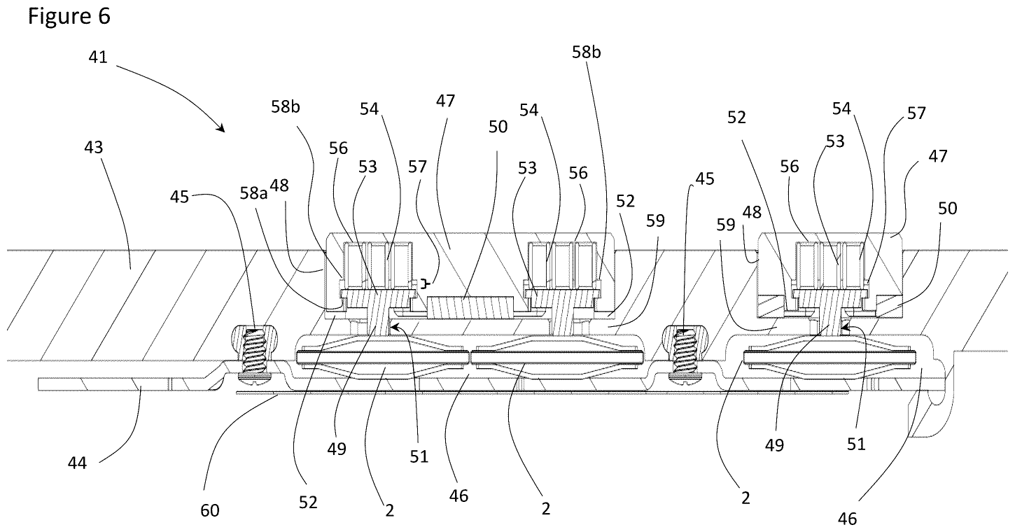

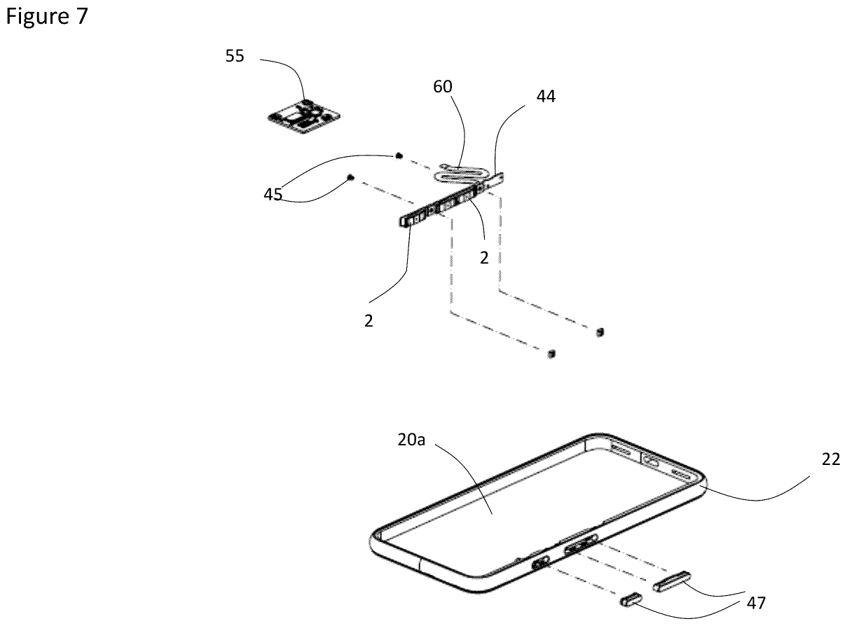

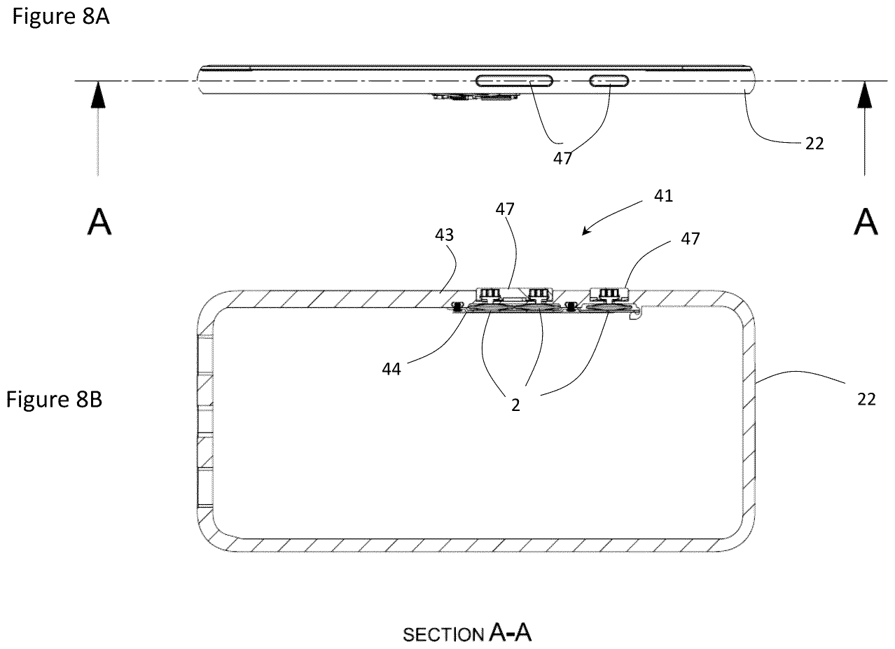

In a third example illustrated in FIGS. 6 to 8, a piezo-electric actuator device 41, includes one or more piezo-electric actuators (piezo) 2 positioned between a top cover 43, e.g. a frame of an electronic device, and a bottom base 44 held together with a suitable fastener, e.g. threaded fasteners 45 or an adhesive. The piezo-electric actuator device 41 may include a single piezo 2 and/or a pair of piezos 2 adjacent each other under a single “double rocker” virtual pushbutton 47. The piezoelectric actuators 2 may be attached to the bottom base 44, e.g. a bracket, and connected to a flexible PCB 60, (FPC) which is also attached between the bottom base 44 and the electronic circuit 55 making those components a subassembly. This subassembly may be fastened to the frame, i.e. top cover 43, e.g. by screws or fasteners 45 and thread inserts attached to the frame.

In the illustrated example, the piezo 2 is positioned within a first recess 46 in the interior surface of the top cover 43, but other arrangements are possible, as hereinbefore described. Similarly, the bottom base 44 comprises a separate bracket connected to the top cover 43, but other arrangements are possible, as hereinbefore described. The virtual pushbutton 47 is received in a second recess 48 in the exterior surface of the top cover 43, and extends outwardly therefrom, although the virtual pushbutton 47 may also be flush therewith or recessed therein. A gasket seal 50, e.g. comprised of a resilient material, such as foam, may be provided between the pushbutton 47 and the top cover 43, for sealing the virtual pushbutton 47, e.g. within the second recess 48 from outside contamination entering the device. The gasket seal 50 may be configured with a thickness to provide a first gap 52 between the pushbutton 47 and the bottom of the second recess 48. Accordingly, the bottom of the second recess 48 provides a hard stop for the virtual pushbutton 47. The virtual pushbuttons 47 may be held in place by the gasket seal 50, e.g. a double side tape, but may be held in place by other means, e.g. interference fit, snap fit, etc.

A thrust member 53, e.g. plate, and a resilient member 54, e.g. spring, may be mounted in a third recess 56 inside the virtual pushbutton 47, and include a plunger or pedestal 49 that extends through a hole 51 in the top cover 43 into contact with the piezo 2. The thrust member 53 may be sandwiched between the virtual pushbutton 47 and the bottom base 44 with one side of the thrust member 53 in contact with the piezo 2, via the pedestal 49, and the other side in contact with the resilient member 54. The nominal height of the resilient member 54 may be larger than the height of the space between the thrust member 53 and the pushbutton 47, whereby once assembled, the resilient member 54 is partially compressed and exerts a preload force on the thrust member 53 to bias the thrust member 53 into contact with a first abutment surface 58a in a groove formed by a first shoulder in the inside surface of the pushbutton 47. The resilient member 54 is configured with a thickness to provide a second gap 57 between the thrust member 53 and a second abutment surface 58b in the groove on the pushbutton 47. In the illustrated example, the thrust member 53 includes extensions, which extend into grooves in opposite sides of the inside surface of the pushbutton 47, the grooves including a shoulder forming the first and second abutment surfaces 58a and 58b at either end thereof defining the limit of travel of the thrust member 53.

According to the third example piezo-electric actuator device 41, the force limiter is integrated directly into the virtual pushbuttons 47. In the illustrated embodiment there are three separate resilient members 54, e.g. for each piezo 2, but one spring per piezo 2 may be sufficient, depending on the space available and other design considerations. The resilient members 54 inside the virtual pushbuttons 47 are pushing with the preload force on the thrust member 53 in the form of the pedestal 49, which extends through the hole 51 in the top cover 43, i.e. extending between the first recess 46 and the second recess 48. The first gap 52 between the virtual pushbutton 47 and the top cover 43, i.e. the bottom of the second recess 48, enables the bottom of the second recess 48 to act as a hard stop, whereby when the force applied on the virtual pushbutton 47 is excessive, the thrust member 53, e.g. pedestal 49, will compress further the resilient member 54 until the first gap 52 is closed (between the pushbutton 47 and the frame, e.g. top cover 43), then any excessive force will be transmitted from the pushbutton 47 to the frame, e.g. the top cover 43, not all to the piezo 2. The deformation of the resilient member 54 will generate a force greater than the preload force on the piezo 2, but less than if no “Force Limiter Mechanism” would be used. The stroke, i.e. the second gap 57, of the thrust member 53, i.e. the pedestal 49, may be greater than the stroke, i.e. the first gap 52, of the virtual pushbutton 47, so the resilient members 54 don't bottom out, e.g. fully compress.

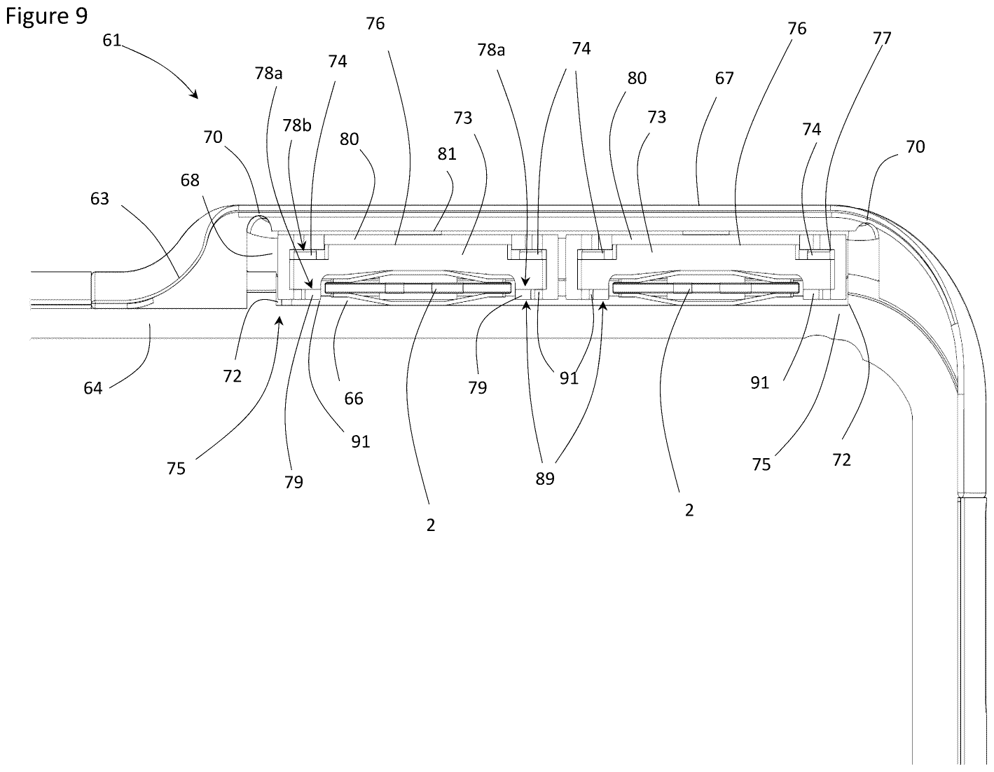

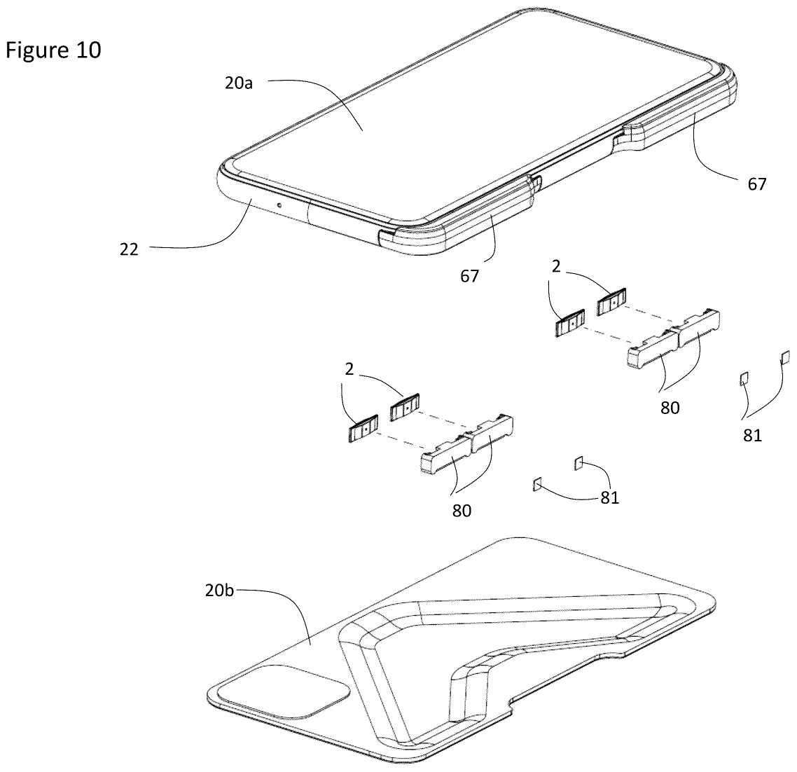

In a fourth example illustrated in FIGS. 9 and 10, a piezo-electric actuator device 61, includes at least one piezo-electric actuator (piezo) 2 positioned between a top cover 63 and a bottom base 64 held together with a suitable fastener, e.g. threaded fasteners or an adhesive. The piezo-electric actuator device 61 may include a single piezo 2 and/or a plurality of piezos 2 adjacent each other under a single virtual pushbutton 67.

In the illustrated example, the piezo 2 is positioned within a first recess 66 in or on the exterior surface of the bottom base 64, but other arrangements are possible, as hereinbefore described. The virtual pushbutton 67 may be received in a second recess 68 in the interior surface of the top cover 63, and extends outwardly therefrom, although the virtual pushbutton 67 may also be flush and contiguous therewith or recessed therein. In the illustrated example, the virtual pushbutton 67 comprises a portion of the top cover 63 defined by thinned virtual hinged sections 70 on either side thereof. Alternatively, a gasket seal e.g. comprised of a resilient material, such as foam, may be provided between the pushbutton 67 and the top cover 63, for sealing the virtual pushbutton 67, e.g. within the second recess 68. A housing element 80 may be provided as an extension of the virtual pushbutton 67 between the virtual pushbutton 67 of the top cover 63 and the bottom base 64, which may be configured with a thickness to provide a first gap 72 between the housing element 80, i.e. the pushbutton 67, and the bottom of the first recess 66 or the second recess 68. Accordingly, the bottom of the first recess 66 or the second recess 68 may provide a hard stop for the housing element 80, i.e. the virtual pushbutton 67. The first recess 66 may be provided within the housing element 80, i.e. within the pushbutton 67.

The force limiter mechanism comprises one or more resilient members 74, e.g. spring, and a thrust member 73 within a third recess 76 within the housing element 80. The housing element 80 includes projections 91 extending into a cavity formed between the top cover 63 and the bottom base 64, i.e. between the first recess 66 and the third recess 76. One side of the projections 91 is configured for engaging a first shoulder 75 in the bottom of the second recess 68 to act as a hard stop for the housing element 80 and therefore the virtual pushbutton 67, while the other side of the projections 91 forms a second shoulder 79 and a first abutment surface 78a for the thrust member 73 to engage. The thrust member 73 is biased into contact with first abutment surface 78a on the projections 91 and is in contact with the piezo-electric actuator 2, while the housing element 80 is in contact with an inner surface of the virtual pushbutton 67, directly or via a shim 81. If an excessive force is applied to the virtual pushbutton 67, as hereinbefore described, then the thrust member 73 will further penetrate into the housing element 80 against the bias of the resilient members 74, to limit the force applied to the piezo 2. With sufficient force, the housing element 80 will close the first gap 72 and contact the frame of the device, e.g. the bottom base 64, so the excessive force will be transmitted to the frame and not to the piezo-electric actuator 2. The virtual pushbutton 67 is compliant, e.g. resilient, so force and displacement applied thereto via a user input force is transmitted to the piezo-electric actuator 2, and vice versa (haptic feedback). The resilient member 74 is configured with a thickness to provide a second gap 77 between the thrust member 73 and the bottom of the third recess 76 in the housing element 80, i.e. a second abutment surface 78b.

One or both of the top cover 3, 23, 43, 63 and the bottom base 4, 24, 44, 64 for this example and any previous or subsequent examples, may be integrated into a frame 22 of an electronic device or be an additional structure connected to the frame 22 of the electronic device. One, two or all of the first recess 6, 26, 46 or 66, the second recess 8, 28, 28 or 68 and the third recess 16, 36, 56 or 76, for this example and any previous and subsequent examples, may be integrated into one or both of the top cover 3, 23, 43, 63 and the bottom base 4, 24, 44, 64. Ideally, a cavity is provided in the side of the frame of the electronic device extending into or through at least one of the top cover 3, 23, 43, 63 and bottom base 4, 24, 44, 64 with projections extending into opposite sides of the cavity forming the first recess 6, 26, 46, the second recess 8, 28, 48 and the third recess 16, 36, 56. The top of the projections may form a first shoulder 15, 29, 59 and the bottom of second recess 8, 28, 48 e.g. defining the hard stop for the pushbutton 7, 27, 47, 67, while the bottom of the projections form a second shoulder 19, 39, 59 and the top of the third recess 16, 36, 56, e.g. a first abutment surface 18a, 38a, 58a, 78a for the thrust member 13, 33, 53, 73. A second abutment surface 18b, 38b, 58b, 78b is provided to support the resilient member 14, 34, 54 and 74, and define the second gap 17, 37, 57, 77, therebetween, which thereby defines the limit of compression of the resilient member. Accordingly, under normal use, the thrust members 13, 33, 53, 73 stays in place, and acts as a rigid body with the frame or the pushbutton, depending on the configuration. When submitted to excessive force, the thrust member “backs off” once it reaches a force equal to the preload force. By having a resilient member with a low stiffness, but a high preload, the distance the button will travel before it hits the hard stop will have only a slight increase on the force applied on the piezo, because the stiffness of the force limiter mechanism will pass from very rigid, i.e. thrust member in contact with the abutting surfaces acts as rigid with the frame, to compliant, i.e. the stiffness of the thrust member is defined by the resilient member.

The foregoing description of one or more example embodiments has been presented for the purposes of illustration and description. It is not intended to be exhaustive or to limit the invention to the precise form disclosed. Many modifications and variations are possible in light of the above teaching. It is intended that the scope of the disclosure be limited not by this detailed description.

We claim:

1. A piezo-electric actuator device for mounting on a frame of an electronic device, comprising:
a first pushbutton mounted on the frame of the electronic device with a first gap between the first pushbutton and a hard stop on the frame;
a first piezo-electric actuator configured for receiving an input force from the first pushbutton and generating a first input voltage signal when the input force exceeds an actuation force;
a first resilient member configured for generating a preload force; and
a first thrust member in contact with the first resilient member configured for applying the preload force to a first abutment surface when the input force is not applied to the first piezo-electric actuator, configured for applying at least a portion of the preload force to the first piezo-electric actuator when the input force is applied to the first piezo-electric actuator, and configured for moving away from the first abutment surface when the input force is greater than the preload force to enable the first pushbutton to engage the hard stop, thereby limiting the input force on the first piezo-electric actuator.

2. The device according to claim 1, wherein the first piezo-electric actuator is also configured for receiving a first output voltage signal and generating a first haptic response to the first pushbutton in response to the input force exceeding the actuation force.

3. The device according to claim 1, further comprising a second gap, larger than the first gap, between the first thrust member and a second abutment surface, whereby the first pushbutton engages the first hard stop on the frame before the first resilient member is fully compressed or the first thrust member engages the second abutment surface.

4. The device according to claim 1, further comprising a resilient seal between the first pushbutton and the frame configured to define the first gap.

5. The device according to claim 1, wherein the first piezo-electric actuator is mounted within a first recess in the frame; wherein the pushbutton is mounted within a second recess in the frame; wherein the resilient member and the thrust member are mounted within a third recess in the frame.

6. The device according to claim 5, wherein the first recess, the second recess and the third recess continuously extend through the frame; and wherein the first recess is in between the second recess and the third recess; wherein a first shoulder between the first recess and the second recess includes the hard stop, and a second shoulder between the first recess and the third recess includes the first abutment surface.

7. The device according to claim 6, wherein the first abutment surface is provided in a top of the third recess.

8. The device according to claim 1, wherein the first pushbutton includes a pedestal extending into contact with the first piezo-electric actuator.

9. The device according to claim 1, wherein the first resilient member comprises a leaf spring, and the first thrust member comprises a plate.

10. The device according to claim 6, wherein the frame comprises:
a base having the third recess extending into an upper side thereof; and
a top cover mounted on the base having the first recess extending into a first side thereof, and the second recess extending into a second side thereof.

11. The device according to claim 1, wherein the pushbutton comprises a virtual button contiguous with an outer portion of the frame.

12. The device according to claim 1, wherein the frame includes a cavity for receiving at least one of the first resilient member, the first thrust member, the first piezo-electric actuator and the first pushbutton;
wherein the cavity includes projections extending into either side thereof; and
wherein the projections form the first hard stop on one side, and the first abutment surface on another side.

13. The device according to claim 1, further comprising:
a second piezo-electric actuator configured for receiving the input force from the first pushbutton and generating a second input voltage signal, and configured for receiving a second output voltage signal and generating a second haptic response to the pushbutton;
a second resilient member configured for generating a second preload force; and
a second thrust member configured for applying the second preload force to a third abutment surface when the input force is not applied to the second piezo-electric actuator and for applying at least a portion of the preload force to the second piezo-electric actuator when the input force is applied to the second piezo-electric actuator, and configured for moving away from the third abutment surface when the input force is greater than the preload force to enable the first pushbutton to engage the hard stop, thereby limiting the input force on the second piezo-electric actuator;
wherein a third gap, larger than the first gap, between the second thrust member and a fourth abutment surface, whereby the first pushbutton engages the frame before the second resilient member is fully compressed or the second thrust member engages the third abutment surface.

14. The device according to claim 1, wherein the resilient member and the thrust member are mounted in the pushbutton.

15. The device according to claim 14, wherein the first abutment surface and a second abutment surface are provided in a groove in the pushbutton.

16. The device according to claim 1, wherein the pushbutton includes a housing element for supporting the resilient member and the thrust member on the piezo-electric actuator and the pushbutton.

17. The device according to claim 16, wherein the housing includes projections extending into a cavity in the frame; wherein one side of the projections are configured for engaging a bottom of the cavity to act as the hard stop for the housing, and another side of the projections forms the first abutment surface.
